(19) United States
(12) Patent Application Publication
(10) Pub. No.: US 2024/0321766 A1
(43) Pub. Date: Sep. 26, 2024

(54) SEMICONDUCTOR DEVICE AND MANUFACTURING METHOD OF THE SAME

(71) Applicant: Samsung Electronics Co., Ltd., Suwon-si (KR)

(72) Inventors: Manhee HAN, Suwon-si (KR); Jimin KIM, Suwon-si (KR)

(73) Assignee: Samsung Electronics Co., Ltd., Suwon-si (KR)

(21) Appl. No.: 18/611,841

(22) Filed: Mar. 21, 2024

(30) Foreign Application Priority Data
Mar. 24, 2023 (KR) 10-2023-0039220
Apr. 28, 2023 (KR) 10-2023-0056637

(51) Int. Cl. H01L 23/544; H01L 21/78

(52) U.S. Cl. CPC H01L 23/544; H01L 21/78; H01L 2223/5446

(57) ABSTRACT

Provided is a semiconductor chip including a substrate, an active layer on the substrate, and a coated layer on side surfaces of the active layer and configured to surround the active layer, wherein an average roughness of the side surfaces of the active layer is greater than an average roughness of an upper surface of the active layer, and at least a portion of the substrate contacts the coated layer.

### CROSS-REFERENCE TO RELATED APPLICATION

This application is based on and claims priority under 35 U.S.C. § 119 to Korean Patent Application Nos. 10-2023-0039220, filed on Mar. 24, 2023 and 10-2023-0056637 filed on Apr. 28, 2023 in the Korean Intellectual Property office, the disclosure of which are incorporated by reference herein in their entirety.

### BACKGROUND

The inventive concepts relate to semiconductor chips and/or manufacturing methods of the semiconductor chip, and more particularly, to semiconductor chips, in which an active layer is removed by using an ablation process, and/or manufacturing methods of the semiconductor chip.

In a manufacturing process of semiconductor chips, a plurality of areas are divided by partition due lines arranged in a lattice shape on the surface of a semiconductor wafer having a roughly disk shape, and in the divided area, devices, such as an integrated circuit (IC) and large scale integration (LSI), are formed. In addition, by cutting the semiconductor wafer along the partition due lines, the area, where a device is formed, is divided to manufacture individual device chips. In the process of dividing the semiconductor wafer, in which a laser beam is irradiated on an active layer on a substrate to remove the active layer along the partition due lines, there is an issue of life reduction of the semiconductor chip due to an application of an external force to the active layer.

### SUMMARY

Some example embodiments of the inventive concepts provide semiconductor chips having a long life by filling cracks therein by a coated layer and/or manufacturing methods of the semiconductor chip.

Some example embodiments of the inventive concepts provide semiconductor chips with a simplified manufacturing method, and/or manufacturing methods of the semiconductor chip, in which the semiconductor chip is partitioned by using an ablation process.

In addition, issues to be solved by the inventive concepts are not limited to those mentioned above, and other issues may be clearly understood by those of ordinary skill in the art from the following descriptions.

According to an aspect of the inventive concepts, a semiconductor chip includes a substrate, an active layer on the substrate, and a coated layer on side surfaces of the active layer and surrounding the side surfaces of the active layer, wherein an average roughness of the side surfaces of the active layer is greater than an average roughness of an upper surface of the active layer, and at least a portion of the substrate contacts the coated layer.

According to another aspect of the inventive concepts, a semiconductor chip includes a substrate, a plurality of active layers on the substrate, and apart from each other in a horizontal direction, and a coated layer in contact with side surfaces of the plurality of active layers and an upper surface of the substrate, wherein a horizontal width of each of the plurality of active layers decreases away from the substrate.

According to another aspect of the inventive concepts, a manufacturing method of a semiconductor chip includes forming a protection layer on an active layer of a substrate, removing a portion of the protection layer and a portion of the active layer along a partition due line inside the active layer, forming a coated layer in a space where the portion of the protection layer and the portion of the active layer are removed, and removing the protection layer on the active layer.

### BRIEF DESCRIPTION OF THE DRAWINGS

Example embodiments will be more clearly understood from the following detailed description taken in conjunction with the accompanying drawings in which:

FIG. 1 is a schematic perspective view of a semiconductor chip according to an example embodiment;

FIG. 2 is a schematic perspective view of a portion of the semiconductor chip of FIG. 1;

FIG. 3 is a schematic longitudinal cross-sectional view of the semiconductor chip of FIG. 2 taken along line B-B′ in FIG. 2;

FIG. 4 is a schematic perspective view of a semiconductor chip according to an example embodiment;

FIG. 5 is a schematic longitudinal cross-sectional view of the semiconductor chip of FIG. 2 taken along line A-A′ in FIG. 4;

FIG. 6 is a schematic enlarged diagram of region III of FIG. 5;

FIG. 7 is a schematic flowchart of a method of manufacturing a semiconductor chip according to an example embodiment;

FIG. 8 is a flowchart of a manufacturing method of a semiconductor device, according to an example embodiment;

FIGS. 9 through 23 are diagrams illustrating a manufacturing method of a semiconductor chip according to a process sequence, according to an example embodiment;

FIG. 24 is a schematic perspective view of a semiconductor processing apparatus according to an example embodiment; and

FIG. 25 is a schematic perspective view of a semiconductor processing apparatus according to an example embodiment.

### DETAILED DESCRIPTION

Because various changes can be applied to the example embodiments disclosed herein and accordingly, example embodiments can have various types, some example embodiments are illustrated in the drawings and detailed descriptions thereof are provided. However, these are not intended to limit the disclosed example embodiments to particular disclosure forms.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

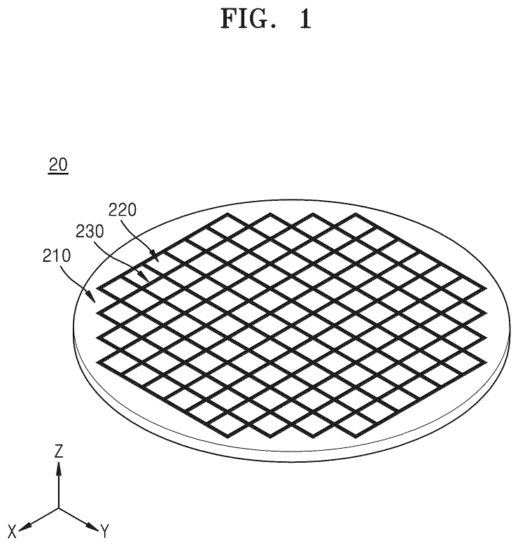

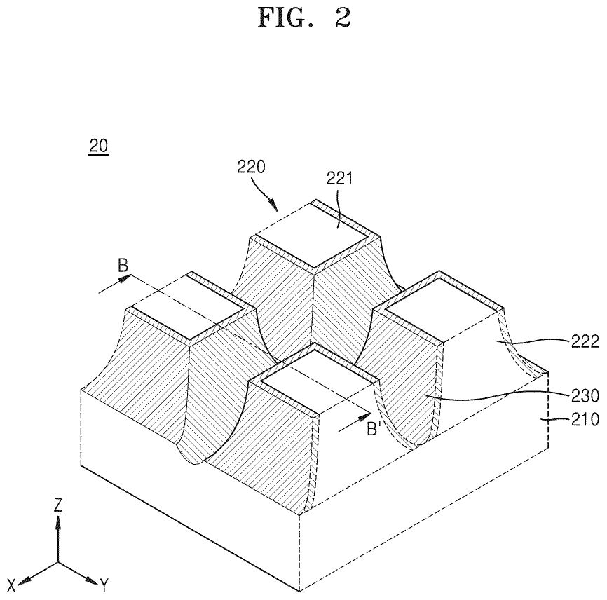

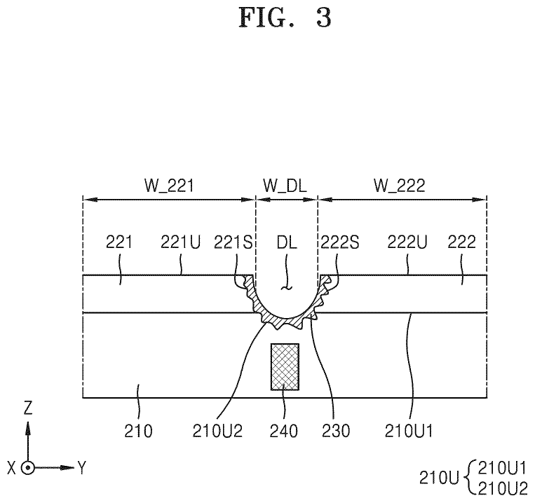

FIG. 1 is a schematic perspective view of a semiconductor chip 20 according to an example embodiment. FIG. 2 is a schematic perspective view of a portion of the semiconductor chip 20 of FIG. 1. FIG. 3 is a schematic longitudinal cross-sectional view of the semiconductor chip 20 taken along line B-B′ in FIG. 2.

Referring to FIGS. 1 through 3, the semiconductor chip 20 may include a substrate 210, a plurality of active layers 220, and a coated layer 230. In some example embodiments, the semiconductor chip 20 may further include a reforming layer 240.

An average roughness may be referred to as the size of fine irregularities that occur on the surface of an object. In the process of molding and cutting an object, a number of small and non-uniform irregularities may occur on the surface of the object. A calculated value of the size of the irregularities may be expressed as an average roughness.

For example, a center line average roughness may virtually show the centerline of a surface in a cross-section of the object. Then, by calculating an area of the irregularities of the object off the center line with the center line of the surface as a reference, and obtaining a mean area per length unit of the center line, a mean line may be shown. The difference between the center line and the mean line shown as such may be defined as the center line average roughness.

In other words, the center line average roughness may be expressed as a value obtained by dividing a line (that is, the mean line), which is smoothened by cutting mountains and filling valleys within a certain measurement length, by the certain measurement length. In this case, the center line may become the standard for distinguishing mountains from valleys.

The average roughness may include a 10-point average roughness in addition to the center line average roughness. Hereinafter, the average roughness may be described based on the center line average roughness, but example embodiments are not limited thereto.

The substrate 210 may include silicon (Si). However, the material of the substrate 210 is not limited thereto. For example, the substrate 210 may include other semiconductor elements, such as germanium (Ge), or compound semiconductors, such as SiC, GaAs, InAs, and InP.

The substrate 210 may have a silicon on insulator (SOI) structure. For example, the substrate 210 may include a buried oxide (BOX) layer. In addition, the substrate 210 may have various device isolation structures such as a shallow trench isolation (STI) structure. The substrate 210 of the semiconductor chip 20 may be referred to as an inactive layer.

In some example embodiments, an upper surface 210U of the substrate 210 may include a first region 210U1 and a second region 210U2 having different average roughnesses. The first region 210U1 may include a region in contact with a plurality of active layers 220, and the second region 210U2 may include a region in contact with the coated layer 230. The average roughness of the first region 210U1 of the upper surface 210U of the substrate 210 may be less than the average roughness of the second region 210U2 of the upper surface 210U of the substrate 210. In some example embodiments, an area of the first region 210U1 of the upper surface 210U of the substrate 210 may be greater than an area of the second region 210U2 of the upper surface 210U of the substrate 210.

A plurality of active layers 220 of the semiconductor chip 20 may be on the upper surface 210U of the substrate 210. Each of the plurality of active layers 220 may include a laminate in which an insulating layer and a functional layer forming a circuit are stacked in the vertical direction (Z-axis direction). A plurality of active layers 220 may be differentiated by a division line DL formed in a lattice shape. In other words, the plurality of active layers 220 may be apart from each other with the division line DL therebetween. In other words, the plurality of active layers 220 may be apart from each other in the horizontal direction (X-axis direction and Y-axis direction) on the upper surface 210U of the substrate 210.

Sidewalls forming the division line DL (e.g., sidewalls of the division line DL) may include two side surfaces 221S and 222S facing each other. The two side surfaces 221S and 222S may face side surfaces of the first active layer 221 and the second active layer 222 that are adjacent to each other among the plurality of active layers 220, respectively. A bottom forming the division line DL (e.g., a bottom of the division line DL) may include the second region 210U2 of the upper surface 210U of the substrate 210. In other words, the bottom of the division line DL may be formed by the plurality of active layers 220 and the substrate 210 of the division line DL. At least one crack may be in the sidewalls and the bottom forming the division line DL. The crack is to be described below.

In some example embodiments, the bottom of the division line DL may have a rounded shape. For example, the cross-section in a direction perpendicular to the direction in which the division line DL extends may have a downwardly concave shape. In other words, a groove in a concave shape may be arranged in a region at which the bottom of the division line DL of the upper surface 210U of the substrate 210 is provided.

The average roughness of the side surfaces 221S and 222S of each of the plurality of active layers 220 may be greater than the average roughness of the upper surfaces 221U and 222U of each of the plurality of active layers 220. For example, the average roughness of the upper surfaces 221U and 222U of each of the plurality of active layers 220 may be less than the average roughness of the sidewalls and the bottom of the division line DL.

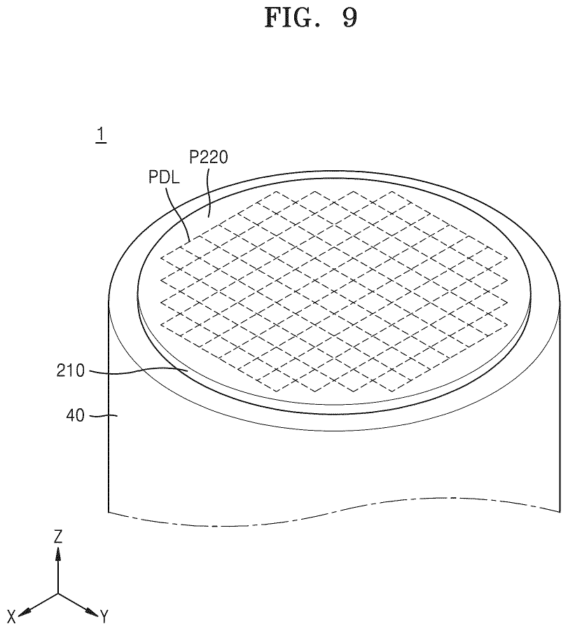

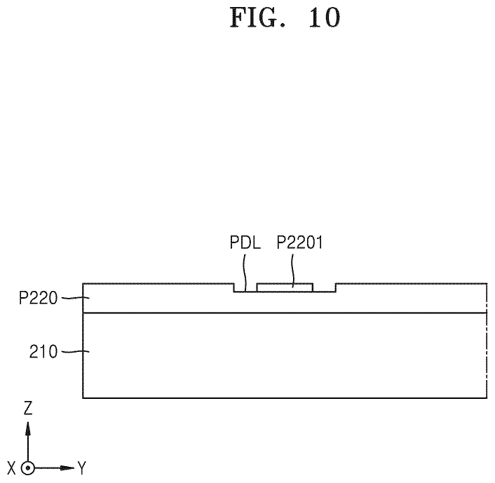

In some example embodiments, the plurality of active layers 220 may have a form in which one laminate (P220 in FIG. 10) is divided by the division line DL. In some example embodiments, a portion of one laminate may be removed along a partition due line (PDL in FIG. 9) by using an ablation process to form the division line DL. Accordingly, one laminate may be divided into the plurality of active layers 220. In this case, the surface of a region of the laminate, on which laser for the ablation processing is irradiated, may become rough.

In other words, in the process of dividing one laminate (P220 in FIG. 10) into the plurality of active layers 220, the average roughness of the surface of the laser-irradiated area of the laminate may be greater than the average roughness of the surface of the area on which the laser is not irradiated. In this case, the laser irradiated area of the surface of the laminate may include the side surfaces 221S and 222S of each of the plurality of active layers 220, and the area of the laminate not irradiated by the laser may include the upper surfaces 221U and 222U of each of the plurality of active layers 220.

In some example embodiments, horizontal widths W_221 and W_222 of each of the plurality of active layers 220 may decrease away from the substrate 210. For example, the side surfaces 221S and 222S of each of the plurality of active layers 220 may be inclined so that the horizontal widths W_221 and W_222 of each of the plurality of active layers 220 narrow away from the substrate 210.

In the process of dividing one laminate (P220 in FIG. 10) into the plurality of active layers 220, the amount of a removed portion of the laminate may decrease away from the upper surfaces 221U and 222U of an adjacent pair of the plurality of active layers 220. Accordingly, the separation distance between the two side surfaces 221S and 222S facing each other of the adjacent first and second active layers 221 and 222 of the adjacent pair of the plurality of active layers 220 may decrease away from the upper surfaces 221U and 222U of the adjacent pair of the plurality of active layers 220. In other words, the horizontal widths W_221 and W_222 of the adjacent pair of the plurality of active layers 220 may decrease away from the substrate 210, and a horizontal width W_DL of the division line DL may increase away from the substrate 210.

The insulating layer forming the plurality of active layers 220 may include a low-k insulation coated layer including an inorganic layer, such as SiO₂ layer, SiOF, and BSG (SiOB), or an organic layer or a polymer layer, such as polyimide-based and parylene-based polymer layers. In some example embodiments, the thickness of the insulating layer may be 10 micrometers (μm).

In addition, a plurality of metal layers P2201 for testing, which include copper (Cu) or aluminum (Al), called a test element group (TEG) for testing the function of an integrated device, may be partially arranged on the partition due line (PDL in FIG. 9). On the other hand, the metal layer P2201 for testing may be included in the laminate.

A plurality of integrated devices of each of the plurality of active layers 220 may include memory elements or logic elements. In some example embodiments, an integrated device, such as an integrated circuit (IC) and a large scale integration (LSI), may be formed on each of the plurality of active layers 220.

For example, the memory elements may include dynamic random access memory (RAM) (DRAM), static RAM (SRAM), flash memory, electrically erasable and programmable ROM (EEPROM), phase-change RAM (RRAM), magnetic RAM (MRAM), or resistive RAM (RRAM).

For example, the logic elements may include an AND, a NAND, an OR, NOR, an exclusive OR (XOR), an exclusive NOR (XNOR), an inverter (INV), an adder (ADD), a buffer (BUF), a delay (DLY), a filter (FIL), a multiplexer (MXT/MXIT), an OAI(OR/AND/INVERTER), an AO(AND/OR), AOI(AND/OR/INVERTER), a D flip-flop, a reset flip-flop, a master-slave flip-flop, a latch, a counter, or buffer elements. In addition, the logic elements may include a central processing unit (CPU), a micro-processor unit (MPU), a graphics processing unit (GPU), or an application processor (AP).

In the semiconductor chip 20 according to some example embodiments, the plurality of integrated devices of each of the plurality of active layers 220 may include memory elements, for example, DRAM elements. For example, the semiconductor chip 20 according to some example embodiments may include a DRAM chip. According to some example embodiments, the semiconductor chip 20, as a DRAM chip, may be used in a high bandwidth memory (HBM) package.

The coated layer 230 of the semiconductor chip 20 may be in contact with the side surfaces 221S and 222S of the plurality of active layers 220 and the upper surface 210U of the substrate 210. The coated layer 230 may be formed on the division line DL formed along the partition due line (PDL in FIG. 9) in a lattice shape, and may be arranged in the lattice shape.

In some example embodiments, the coated layer 230 may be conformally formed on the side surfaces 221S and 222S of a plurality of active layers 220. The coated layer 230 may be formed on portions of the side surfaces 221S and 222S of the plurality of active layers 220 and on the upper surface 210U of the substrate 210, and the coated layer 230 may have a “U” shape. For example, the coated layer 230 may be formed to have a constant thickness on the side surfaces 221S and 222S of the plurality of active layers 220 but is not limited thereto, and the thickness of the coated layer 230 may increase toward the upper surface 210U of the substrate 210.

In some example embodiments, the thickness of the coated layer 230 may be about 1 μm to about 10 μm. In some example embodiments, the coated layer 230 may include an inorganic material, such as silicon dioxide and ceramic. In some example embodiments, the average roughness of the surface of the coated layer 230 may be less than the average roughness of the side surfaces of the plurality of active layers, and accordingly, the coated layer 230 may not be relatively more damaged by an external force than the plurality of active layers 220.

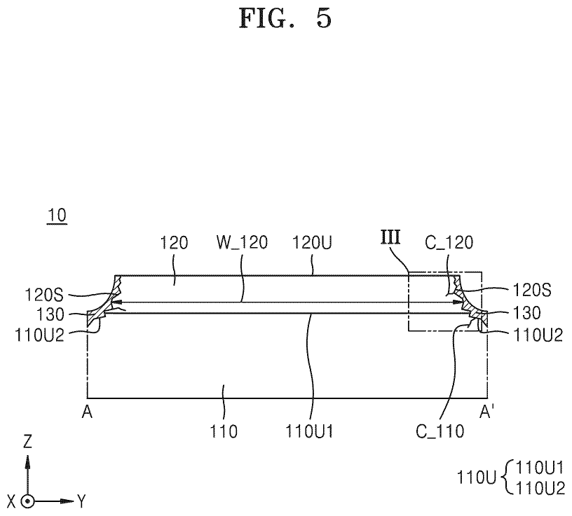

In some example embodiments, a plurality of cracks (C_120 and C_110 in FIG. 5) may be in the sidewall and the bottom of the division line DL, respectively. In other words, a crack may be formed in a surface having a relatively greater average roughness. For example, cracks may be formed in the side surfaces 221S and 222S of each of the plurality of active layers 220 and on the second region 210U2 of the upper surface 210U of the substrate 210, by the external force generated in the operation of dividing one laminate (P220 in FIG. 10) into the plurality of active layers 220.

In some example embodiments, the coated layer 230 may fill cracks in the sidewalls and bottom of the division line DL. In other words, the coating solution may be applied to the side surfaces 221S and 222S of each of the plurality of active layers 220 and the second region 210U2 of the upper surface 210U of the substrate 210, and in the process of curing, may flow into a plurality of cracks so that the coated layer 230 fills the inside of the plurality of cracks.

The reforming layer 240 of the semiconductor chip 20 may be included in the substrate 210. The reforming layer 240 may be arranged along the partition due line. For example, the reforming layers 240 may be apart from the division line DL in the vertical direction. The reforming layer 240 may be formed by irradiating laser on the lower surface of the substrate 210, and may include thermal stress and cracks to be easily damaged by external force. Accordingly, the semiconductor chip 20 may be divided into a plurality of semiconductor chips along the reforming layer 240.

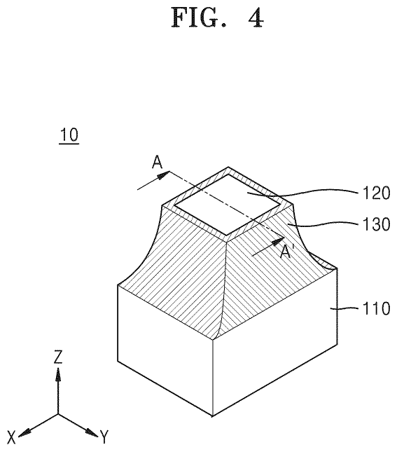

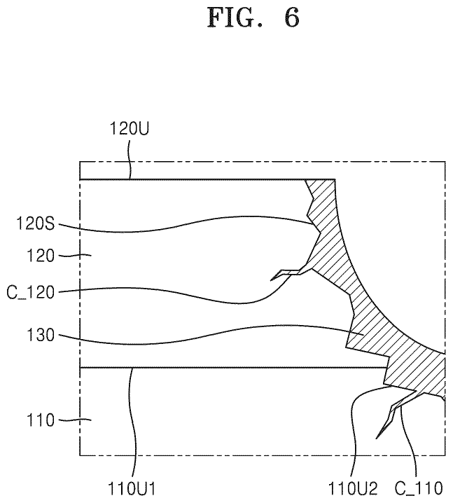

FIG. 4 is a schematic perspective view of the semiconductor chip 10 according to an example embodiment. FIG. 5 is a schematic longitudinal cross-sectional view of the semiconductor chip 10 of FIG. 4 taken along line A-A′ in FIG. 4. FIG. 6 is a schematic enlarged diagram of region III in FIG. 5.

Referring to FIGS. 4 through 6, the semiconductor chip 10 may include a substrate 110, an active layer 120, and a coated layer 130. The semiconductor chip 20 of FIG. 2 is divided along the partition due line (PDL in FIG. 9) to form an individual semiconductor chip 10 of FIG. 4. Hereinafter, duplicate descriptions between the semiconductor chip 10 of FIG. 4 and the semiconductor chip 20 of FIG. 2 are omitted, and only the difference therebetween is described.

The substrate 110 of the semiconductor chip 10 may include Si. However, the material of the substrate 110 is not limited thereto. The substrate 110 of the semiconductor chip 10 may be referred to as an inactive layer. A portion of the substrate 110 may be in contact with the active layer 120, and the other portion thereof may be in contact with the coated layer 130.

An upper surface 110U of the substrate 110 may include a first region 110U1 and a second region 110U2. The first region 110U1 may include a region in contact with the active layer 120, and the second region 110U2 may include a region in contact with the coated layer 130. In some example embodiments, the first region 110U1 may be surrounded by the second region 110U2. For example, the first region 110U1 may have a rectangular shape, and the second region 110U2 may have a shape surrounding four sides of the first region 110U1.

The average roughness of the upper surface 110U of the substrate 110 in the second region 110U2 may be greater than that in the first region 110U1. In some example embodiments, the upper surface 110U of the substrate 110 in the second region 110U2 may have irregularities thereon during an ablation process, and the average roughness thereof may be greater than the average roughness of the upper surface 110U of the substrate 110 in the first region 110U1.

The substrate 110 may include a downwardly concave groove in the second region 110U2. In other words, the second region 110U2 may have a curved surface unlike the first region 110U1. The upper surface 120U of the active layer 120 in the second region 110U2 of the upper surface 110U of the substrate 110 may be partially removed during an ablation process, and the upper surface 110U of the substrate 110 may have a downwardly concave groove in the second region 110U2.

The active layer 120 of the semiconductor chip 10 may include a plurality of integrated devices. In some example embodiments, integrated devices, such as an IC and LSI, may be formed on the active layer 120. In addition, the active layer 120 may include integrated devices on a plurality of active layers (220 in FIG. 1) described above.

The active layer 120 may be on the substrate 110. A horizontal width W_120 of the active layer 120 may narrow away from the substrate 110. For example, a side surface 120S of the active layer 120 may have a plane or curved surface, which is inclined, so that the horizontal width W_120 of the active layer 120 narrows away from the substrate 110.

The average roughness of the upper surface 120U of the active layer 120 may be less than the average roughness of the side surface 120S of the active layer 120. In other words, the upper surface 120U of the active layer 120 may have less irregularities than the side surface 120S of the active layer 120.

For example, an area, where a portion of the laminate has been removed by an ablation process, may include the side surface 120S of the active layer 120, and an area, where the laminate has not been removed, may include the upper surface 120U of the active layer 120. The side surface 120S of the active layer 120 may be formed as one laminate is divided into a plurality of active layers. In the process of forming the side surface 120S of the active layer 120, irregularities may occur on the side surface 120S of the active layer 120 by an ablation process. Accordingly, by an ablation process, the average roughness of the side surface 120S of the active layer 120 may be greater than the average roughness of the upper surface 120U of the active layer 120.

In some example embodiments, the area of the lower surface of the active layer 120 may be less than the area of the upper surface 110U of the substrate 110. In other words, a portion of the upper surface 110U of the substrate 110 may not be in contact with the lower surface of the active layer 120. In other words, a portion of the active layer 120 may be removed by an ablation process, and the area of the lower surface of the active layer 120 may be less than the area of the upper surface 110U of the substrate 110.

The coated layer 130 of the semiconductor chip 10 may surround the side surface 120S of the active layer 120. In some example embodiments, all of the side surfaces 120S of the active layer 120 may be in contact with the coated layer 130. The coated layer 130 may be in contact with at least some portions of the side surface 120S of the active layer 120 and the upper surface 110U of the substrate 110. The coated layer 130 may be in contact with the side surface 120S of the active layer 1200, and coplanar with the side surface 120S of the active layer 120 and the upper surface 110U of the substrate 110. For example, an area coplanar with the side surface 120S of the active layer 120 and the upper surface 110U of the substrate 110 may form a portion of the division line (DL in FIG. 3) described above.

The coated layer 130 may be formed conformally on the side surfaces 120S of the active layer 120. In other words, the coated layer 130 may have a constant thickness with respect to the side surfaces 120S of the active layer 120. In other words, the coated layer 130 may include one surface contacting the side surface 120S of the active layer 120 and the other surface facing the one surface. In this case, the distance between the one surface and the other surface of the coated layer 130 may be constant. For example, the coated layer 130 may include a curved surface formed along the side surface 120S of the active layer 120.

At least one of the active layer 120 and the substrate 110 may include at least one crack. In some example embodiments, a plurality of cracks may include a first crack C_120 and a second crack C_110. The first crack C_120 may include a crack in the side surface 120S of the active layer 120, and the second crack C_110 may include a crack in the upper surface 110U of the substrate 110. The second crack C_110 may be in the second region 110U2 of the upper surface 110U of the substrate 110. The first crack C_120 may include a gap extending from the side surface 120S of the active layer 120 to the inside of the active layer 120. The second crack C_110 may include a gap extending from the second region 110U2 of the upper surface 110U of the substrate 110 to the inside of the substrate 110.

During an ablation process, the first crack C_120 and the second crack C_110 may be formed in a portion of the semiconductor chip 10. In other words, in the process of removing a portion of the semiconductor chip 10, at least one crack may occur in the side surface 120S of the active layer 120 or in the upper surface 110U of the substrate 110 that is irradiated with the laser. A plurality of cracks included in the semiconductor chip 10 may cause damage and failure of the semiconductor chip 10.

The coated layer 130 may fill a plurality of cracks formed in at least one of the active layer 120 and the substrate 110. When at least one of the first crack C_120 in the side surface 120S of the active layer 120 and the second crack C_110 on the upper surface 110U of the substrate 110 is formed, the coated layer 130 may fill the inside of at least one of the first crack C_120 and the second crack C_110. In the process of applying a liquidous coating solution to the side surface 120S of the active layer 120 and the upper surface 110U of the substrate 110, the coating solution may flow into the first crack C_120 and the second crack C_110 formed in the ablation process. After the coating solution is dried and cured, the coated layer 130 may be formed inside the first crack C_120 and the second crack C_110.

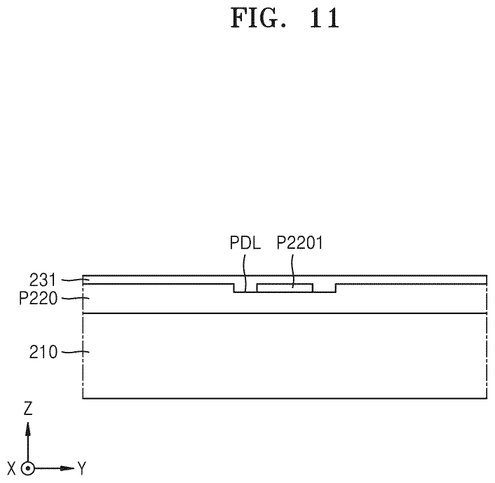

In some example embodiments, the coated layer 130 may cover the side surface 120S of the active layer 120 but may not cover the upper surface 120U of the active layer 120. In other words, the side surface 120S of the active layer 120 may be covered by the coated layer 130 and may not be exposed to the outside, and the upper surface 120U of the active layer 120 may not be covered by the coated layer 130 and may be exposed to the outside. For example, in the process of forming the coated layer 130 on the side surface 120S of the active layer 120, after a protection layer (231 in FIG. 11) is temporarily formed on the upper surface 120U of the active layer 120, the coated layer 130 may be formed, the protection layer may be removed, and the coated layer 130 may not cover the upper surface 120U of the active layer 120.

The second region 110U2 of the upper surface 110U of the substrate 110 and the side surface 120S of the active layer 120 may include damage, such as thermal stress and cracks, due to an ablation process. Damage in the semiconductor chip 10 may cause the semiconductor chip 10 to easily be broken or fail by the external force, thereby reducing the lifespan of the semiconductor chip 10. In some example embodiments of the inventive concepts, the coated layer 130 may cover the damaged portion of the semiconductor chip 10, and protect the damaged portion thereof from the outside. Accordingly, the life of a semiconductor chip may be extended.

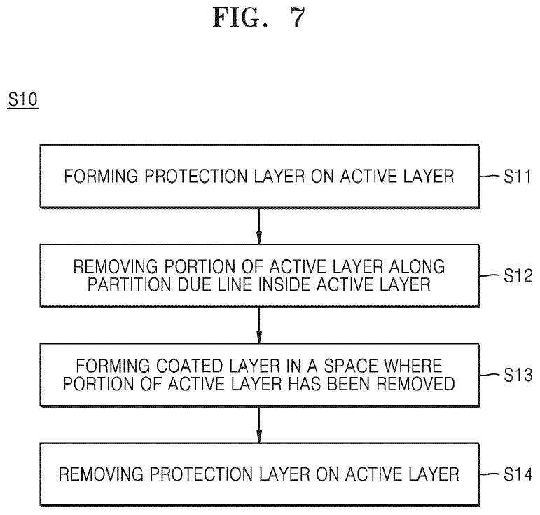

FIG. 7 is a schematic flowchart of a method of manufacturing a semiconductor chip according to an example embodiment.

According to FIG. 7, the manufacturing method of the semiconductor chip may include forming a protection layer on an active layer (S11), removing a portion of the active layer along a partition due line inside the active layer (S12), forming a coated layer in a space, where the portion of the active layer is removed (S13), and removing the protection layer from the active layer (S14).

The manufacturing method of the semiconductor chip of FIG. 7 illustrates operation of forming a division line on a substrate of the semiconductor chip (S10). In some example embodiments, the operation of removing a portion of the active layer (S12) may be performed by using an ablation processing, in which laser is irradiated along a partition due line. An ablation process may include a processing method, in which laser is concentrated on the surface of a sample. In other words, an ablation process may include a processing method, in which laser is condensed on the surface of an active layer to remove the active layer of the region on which the laser is condensed.

During an ablation process, the average roughness of the surface of the active layer in the region, where the laser is concentrated, may be greater than the average roughness of the surface of the active layer in the region where the laser is not concentrated. In addition, a plurality of cracks may be formed in the surface of the active layer of the region on which the laser is condensed.

A protection layer may be formed on the upper surface of the active layer before a portion of the active layer is removed, and accordingly, a phenomenon, in which particles generated during an ablation process are attached to the upper surface of the active layer, may be prevented or mitigated. In addition, in the process of forming the coated layer, the protection layer may suppress a phenomenon in which the coating solution splashes on the upper surface of the active layer. Because the upper surface of the active layer is protected by the protection layer, and thus, laser is not concentrated thereon, the average roughness of the upper surface of the active layer may be less than the average roughness of the side surface of the active layer on which the laser is concentrated.

In the operation of forming the coated layer (S13), the coated layer may be formed on the surface of the active layer, on which the laser is concentrated, and on the surface of the substrate on which the laser is concentrated. In some example embodiments, the coated layer may fill a plurality of cracks formed in the surface of the active layer and the surface of the substrate, and may suppress a phenomenon in which a semiconductor chip is damaged or broken by an external force. The coated layer may have greater strength or hardness than the active layer and the substrate, which are damaged by the laser.

In some example embodiments, an operation of forming the coated layer (S13), may include an operation of applying the coating solution on the active layer. In some example embodiments, a method of applying the coating solution on the active layer may include a method of applying the coating solution on the division line in a spray method. In other words, the coating solution may be applied to a region, from which the active layer is removed by using an ablation process, by using an aerosol method. In some example embodiments, a method of applying the coating solution on the active layer may include a method of applying the coating solution on the division line in a brush method. In other words, the coating solution may be applied by bringing a brush absorbing the coating solution into contact with an area where the active layer is removed by using an ablation process.

In some example embodiments, an operation of forming the coated layer (S13) may further include an operation of curing the coating solution. The coated layer may be formed as the coating solution is coagulated. In some example embodiments, the coating solution may be coagulated by natural drying, thermosetting, or photo-curing. In some example embodiments, the coating solution may include a material that is cured by ultraviolet or infrared heat. In some example embodiments, the coating solution may include a material that is cured by hot air. In some example embodiments, the coating solution may include a material cured by ultraviolet or infrared light.

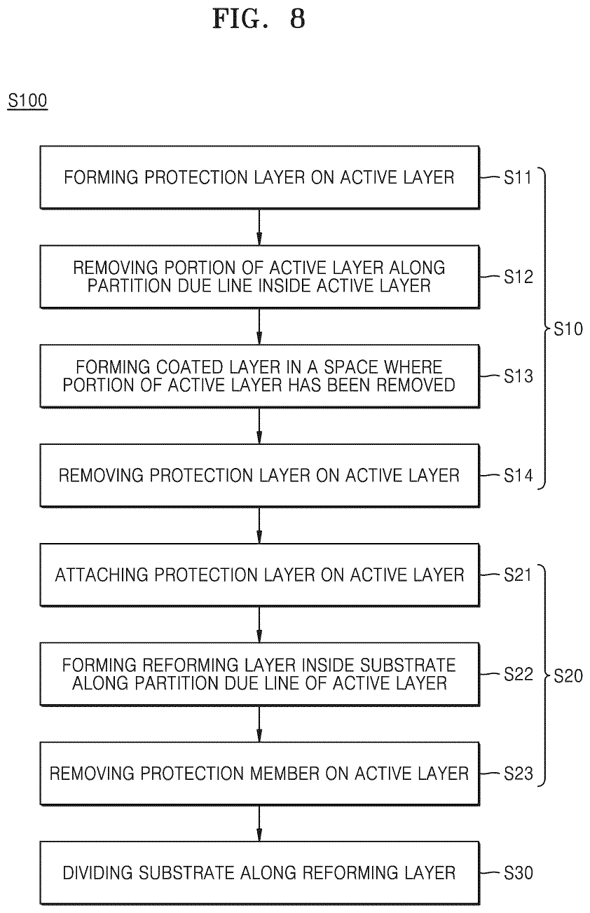

FIG. 8 is a flowchart of a manufacturing method of a semiconductor device, according to an example embodiment.

Referring to FIG. 8, the method of manufacturing a semiconductor chip (S100) may include an operation of forming a division line on a substrate of a semiconductor chip (S10) and an operation of dividing the substrate (S20). In FIG. 8, an operation of forming the division line (S10) may be performed before an operation of dividing the substrate (S20), but is not limited thereto, and the operation of dividing the substrate (S20) may be performed before the operation of forming the division line.

In some example embodiments, the manufacturing method of the semiconductor chip (S100) may further include an operation of polishing a lower surface of the substrate facing an upper surface of the substrate. Thus, by polishing the lower surface of the substrate, the thickness of the semiconductor chip may be reduced. For example, an operation of polishing the lower surface of the substrate may be performed by using a grinding/polishing apparatus.

The operation of forming the division line on the substrate (S10) may include forming a protection layer on an active layer (S11), removing a portion of the active layer along a partition due line inside the active layer (S12), forming a coated layer in a space, where the portion of the active layer is removed (S13), and removing the protection layer from the active layer (S14). In some example embodiments, the operation of forming the division line on the substrate (S10) may include operation of forming the division line on the substrate described with reference to FIG. 7.

The operation of dividing the substrate (S20) may include an operation of attaching a protection member on an active layer (S21), an operation of forming a reforming layer in the substrate along the partition due line of an active layer (S22), an operation of removing a protection member from the active layer (S23), and an operation of dividing the substrate along the reforming layer (S24).

The protection member attached onto the active layer may include a protection tape for protecting the active layer. In other words, in the operation of attaching the protection member onto the active layer, the protection tape may be adhered to the active layer. In some example embodiments, the protection tape may have a form in which an acrylic resin-based adhesive layer is applied at a thickness of 5 μm on a surface of a sheet-type material including polyvinyl chloride (PVC) having a thickness of 100 μm.

In the operation of forming a reforming layer inside the substrate (S22), by moving a lower surface of the substrate to a laser beam irradiation region, where a condenser of a stealth dicing device is arranged, one end of a desired (or alternatively, pre-defined) partition due line may be arranged directly under the condenser of the stealth dicing device. In this case, the center position in the width direction of the partition due line may be directly under the condenser. In addition, when, by irradiating a pulse laser beam of a frequency having transmittance with respect to the substrate from a condenser, and moving a chuck table at a desired (or alternatively, pre-defined) moving speed in the horizontal direction (X direction and/or Y direction), the irradiation position of the condenser reaches the other end of the partition due line, the irradiation of the pulse laser beam may be stopped and the movement of the chuck table may be stopped.

In the process of forming the reforming layer, by aligning the condensing point of the pulse laser beam to the middle position in the thickness direction of the substrate, the reforming layer 240 may be formed inside the substrate 210 along the partition due line.

In the operation of dividing the substrate along the reforming layer (S23), by applying the external force to the substrate, the substrate may be divided into individual semiconductor chips along the partition due line where the reforming layer 240 is formed. In some example embodiments, by applying tension to the tape attached to the substrate, the substrate may be divided along the reforming layer. In other words, because the reforming layer inside the substrate has weaker strength and hardness than other regions of the substrate, the reforming layer may be easily damaged. The weakened reforming layer may be easily damaged by tension, and the substrate may be divided along the reforming layer.

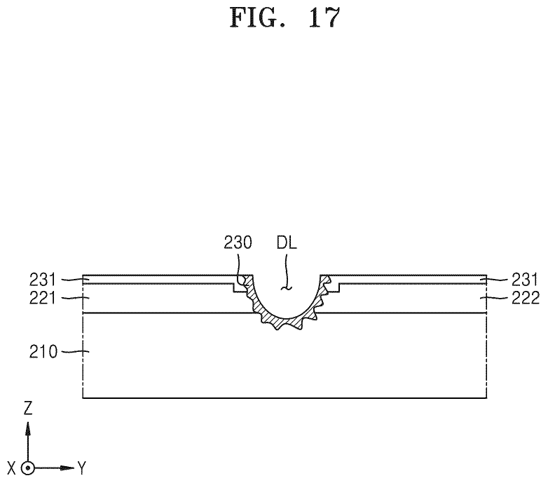

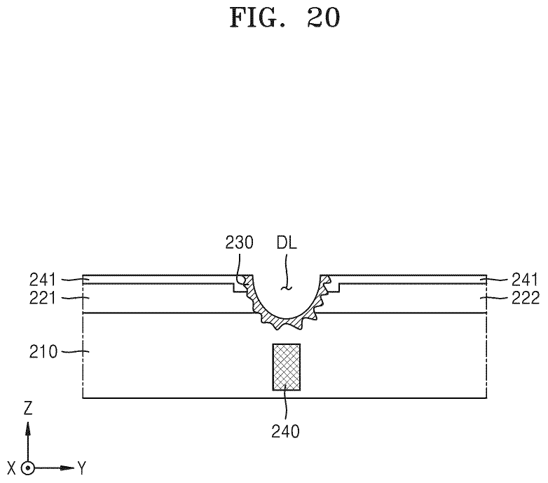

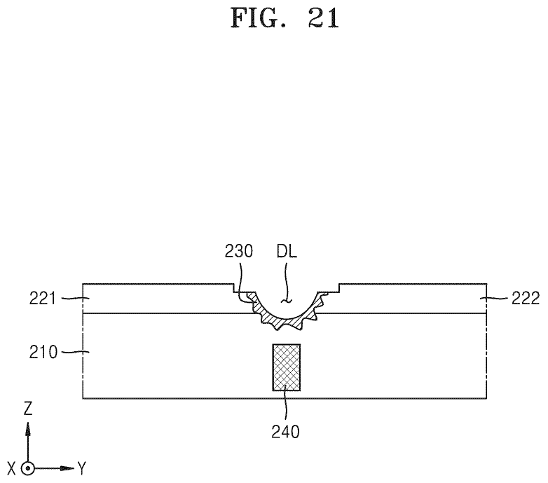

FIGS. 9 through 23 are diagrams illustrating a manufacturing method of a semiconductor chip according to a process sequence, according to an example embodiment.

Hereinafter, the manufacturing method of the semiconductor chip (S100) of FIG. 8 is described with reference to FIGS. 9 through 23. In FIGS. 9 through 23, a method of forming the coated layer 230 after forming the reforming layer 240 inside the substrate 210 is described but is not limited thereto.

Referring to FIGS. 9 and 10, the substrate 210 may be mounted on a chuck table 40 so that the lower surface of the substrate 210 is positioned to face downward. A laminate P220 may be on the upper surface of the substrate 210, and the laminate P220 and the substrate 210 may include a partition due line PDL. In some example embodiments, the chuck table 40 may include an electrostatic chuck, which fixes a substrate by using electrostatic force or a vacuum chuck which fixes a substrate by using vacuum. In some example embodiments, the substrate 210 may be fixed on the chuck table 40 by using an adhesive tape.

The laminate P220 on the upper surface of the substrate 210 may further include the metal layer P2201 for testing. The metal layer P2201 for testing may be on the partition due line PDL. The metal layer P2201 for testing may include Cu or Al, which is referred to as a TEG for testing the function of an integrated device.

Next, referring to FIG. 11, a protection layer 231 may be formed on the laminate P220. In some example embodiments, the chuck table 40 may be configured to spin with respect to the vertical direction (Z-axis direction). A water-soluble liquidous resin may be applied on the laminate P220 fixed on the chuck table 40, the chuck table 40 may rotate, and the water-soluble liquidous resin on the laminate P220 may spread to the entire upper surface of the laminate P220. In this manner, a protection layer 231 including a water-soluble liquidous resin may be formed on the laminate P220. In some example embodiments, the water-soluble liquidous resin may include polyvinyl alcohol (PVA), poly ethylene glycol (PEG), and poly ethylene oxide (PEO). In some example embodiments, the thickness of the protection layer 231 may be about 0.2 μm to about 10 μm.

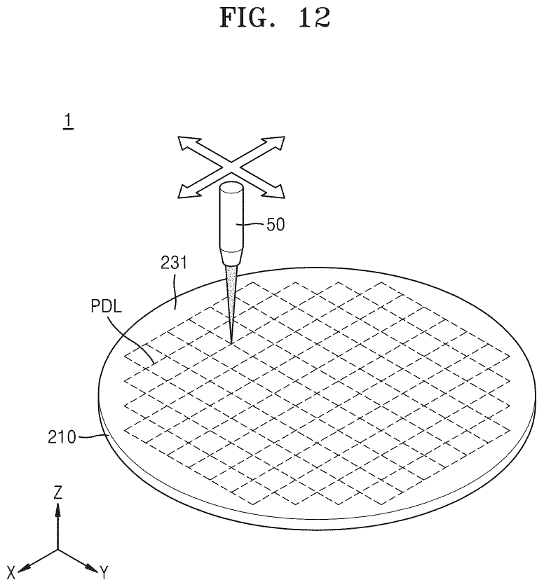

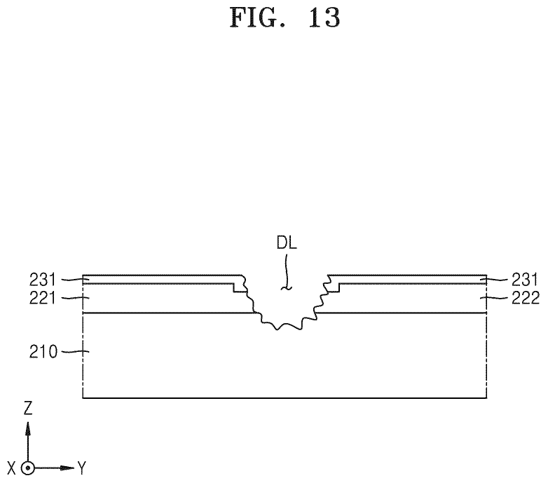

Next, referring to FIGS. 12 and 13, a condenser 50 of an active layer partition device 1 may condense laser on the upper surface of the laminate P220. The condenser 50 may condense laser on the upper surface of the laminate P220, and perform an ablation process to remove a portion of the laminate P220. In some example embodiments, as the chuck table 40 moves in the horizontal direction (X-axis and Y-axis directions), the substrate 210 may move together, and the condenser 50 may concentrate laser from one end to the other end of the laminate P220. In some example embodiments, as illustrated in FIG. 12, the condenser 50 may move horizontally from one end to the other end of the substrate 210, and may concentrate a laser on the upper surface of the laminate P220.

When the condenser 50 concentrates laser on the surface of the laminate P220, a portion of the laminate P220 may be removed and separated to form a plurality of active layers. In this case, the division line DL may be formed between the first and second active layers 221 and 222, and a downwardly concave groove may be formed in the upper surface of the substrate 210. As the distance from the top surfaces of the first and second active layers 221 and 222 decreases, the amount of the laminate P220 removed by the laser may decrease, and the horizontal width of the division line DL may be narrowed towards the substrate 210. The upper surfaces of the first and second active layers 221 and 222 may be protected by the protection layer 231 from particles generated while a portion of the laminate P220 is removed.

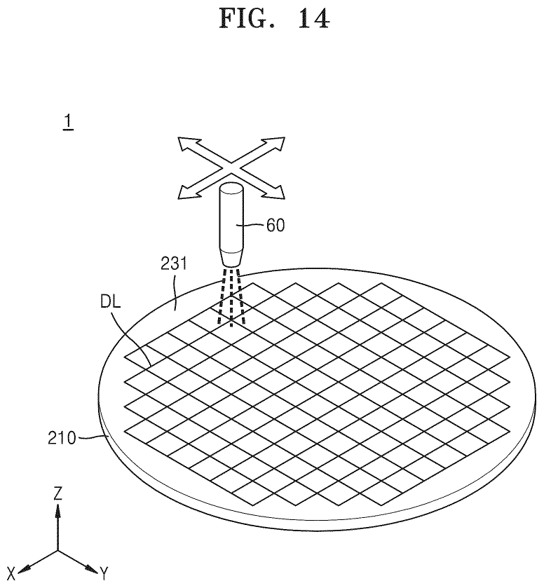

Referring to FIGS. 14 through 17, an applicator 60 of the active layer partition device 1 may apply a coating solution on the division line DL to form the coated layer 230. The coated layer 230 may be conformally formed on the division line DL by using the applicator 60.

In some example embodiments, as the chuck table 40 moves in the horizontal direction (X direction and/or Y direction), the substrate 210 may move together, and the applicator 60 may apply a coating solution on the division line DL. In some example embodiments, as illustrated in FIG. 14, while the applicator 60 moves in the horizontal direction on the division line DL, the applicator 60 may apply a coating solution on the division line DL.

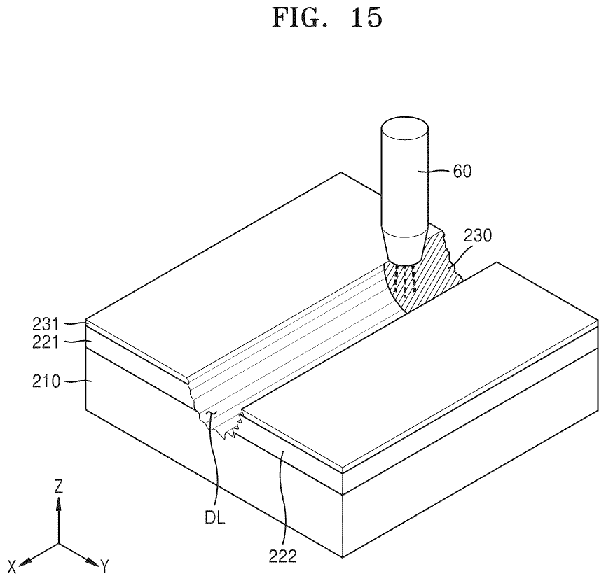

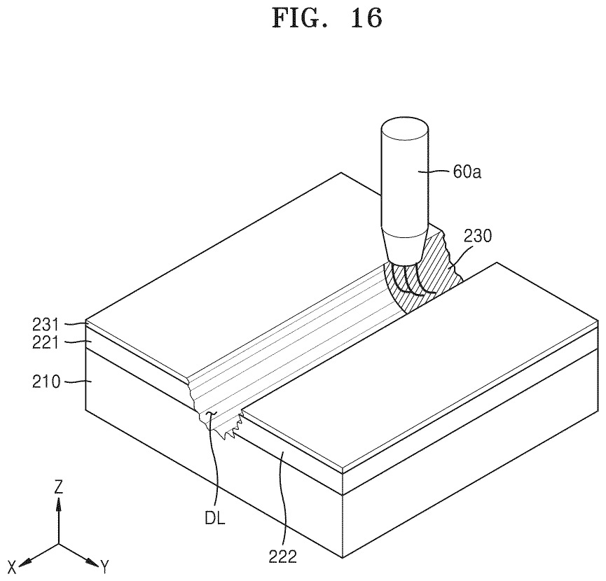

In some example embodiments, referring to FIG. 15, the applicator 60 may apply a coating solution on the division line DL in a spray method. In some example embodiments, referring to FIG. 16, an applicator 60a may apply a coating solution on the division line DL in a brush method. The brush method may mean a method in which a brush having absorbed a coating solution contacts the division line DL and applies a coating solution on the division line DL.

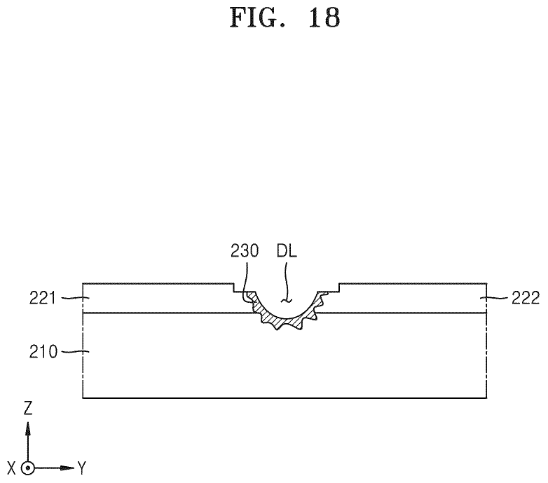

Next, referring to FIG. 18, the protection layer 231 on the first and second active layers 221 and 222 may be removed. The protection layer 231 may suppress a phenomenon in which particles and a coating solution reach the upper surfaces of the first and second active layers 221 and 222.

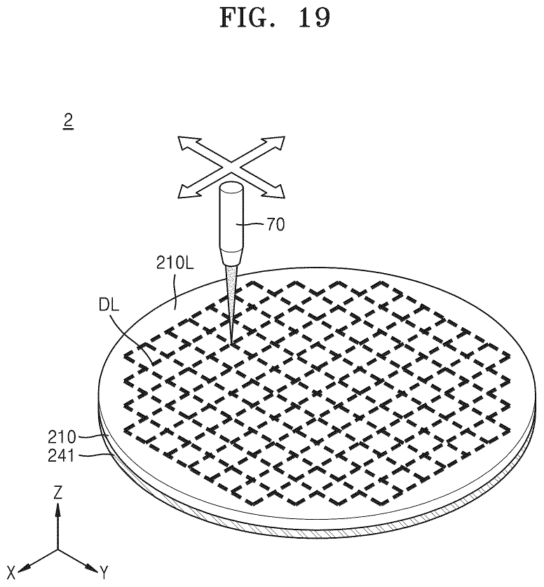

Next, referring to FIGS. 19 through 21, the reforming layer 240 may be formed inside the substrate 210 through a substrate partition device 2. The substrate partition device 2 may include a chuck table (not illustrated) and a condenser 70. The substrate 210 may be mounted on the chuck table 40 so that a protection member 241 is attached on the first and second active layers 221 and 222, and the protection member 241 contacts the chuck table 40.

Thereafter, the chuck table 40 or the condenser 70 moves in the horizontal direction, and the laser emitted by the condenser 70 is condensed on a lower surface 210L of the substrate 210, to form the reforming layer 240 along the partition due line inside the substrate 210. As the reforming layer 240 is formed inside the substrate 210, cracks may be formed in the substrate 210 near the reforming layer 240. In this case, the location where the laser of the condenser 70 is condensed, that is, the location where the reforming layer 240 is formed, may include a location where a crack formed by the reforming layer 240 reaches the division line DL. Next, after the reforming layer 240 is formed inside the substrate 210, the protection member 241 attached to the active layer may be removed.

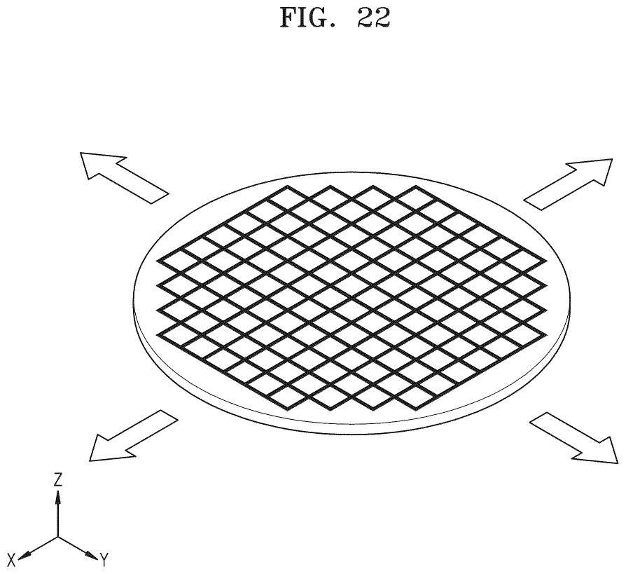

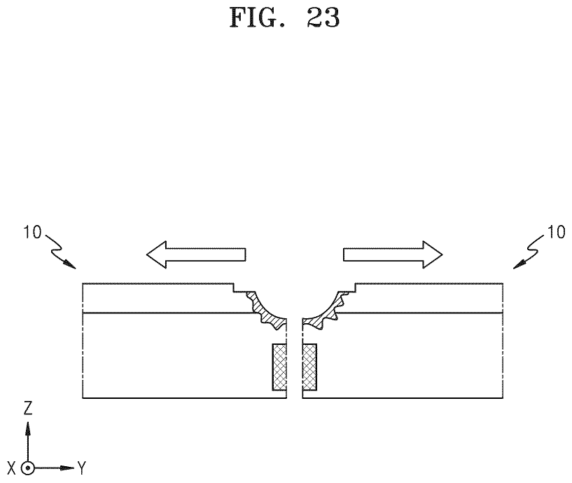

Next, referring to FIGS. 22 and 23, the substrate 210 may be divided along the reforming layer 240. A plurality of semiconductor chips 10 each including one active layer (120 in FIG. 4) may be manufactured, by dividing the substrate 210. The reforming layer 240 may be easily damaged by an external force compared to other regions of the substrate 210. Accordingly, by generating tension in the substrate 210 and breaking the substrate 210 along the reforming layer 240, the substrate 210 may be divided into the plurality of semiconductor chips 10.

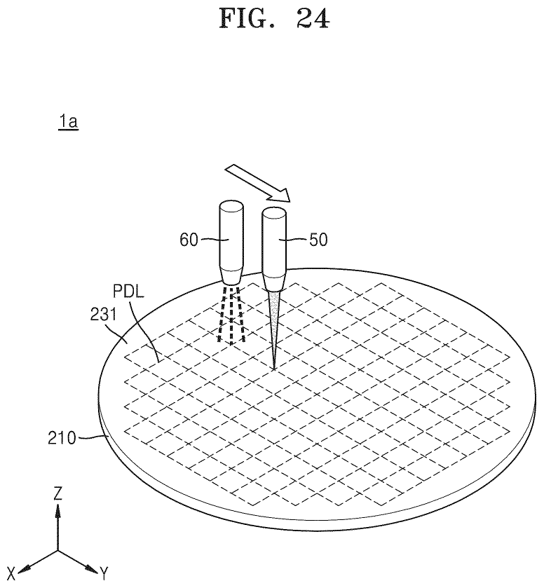

FIG. 24 is a schematic perspective view of a semiconductor processing apparatus 1a according to an example embodiment.

Referring to FIG. 24, a semiconductor processing apparatus 1a may include the chuck table (40 in FIG. 9), the condenser 50, and the applicator 60. The semiconductor processing apparatus 1a may include a device for forming the division line (DL in FIG. 2) on the laminate P220.

The chuck table may mount the substrate 210 and an active layer thereon. The substrate 210 may be mounted on the chuck table so that the chuck table contacts the lower surface of the substrate 210. In some example embodiments, a chuck table may include an electrostatic chuck, which fixes a substrate by using electrostatic force or a vacuum chuck which fixes a substrate by using vacuum. In some example embodiments, the substrate 210 may be fixed on the chuck table by using an adhesive tape.

The condenser 50 may condense laser on the surface of the laminate P220. The condenser 50 may perform an ablation process for removing the laminate P220 of the region in which the laser has been condensed. A point, at which the laser of the condenser 50 is condensed, may be on the upper surface of the laminate P220. The condenser 50 may include the condenser (50 in FIG. 12) of the active layer partition device 1 described above.

The applicator 60 may apply a coating solution to the division line (DL in FIG. 2). The applicator 60 may include the applicators 60 or 60a of the active layer partition device 1 described above. The applicator 60 may be arranged in line with the condenser 50. In other words, the applicator 60 may be arranged in a line with the condenser 50 to be in a direction in parallel with the moving direction of the condenser 50. The applicator 60 and the condenser 50 may move along the partition due line PDL.

In some example embodiments, the moving direction of the applicator 60 may be the same as the moving direction of the condenser 50. The applicator 60 may follow the movement of the condenser 50, and apply a coating solution to a region, where the condenser 50 condenses laser. In other words, the condenser 50 and the applicator 60 may be sequentially arranged in the moving direction of the condenser 50. In other words, as the condenser 50 and the applicator 60 move in the same direction, the condenser 50 may pass the upper portion of the partition due line PDL of the laminate P220 in advance, and the applicator 60 may pass later.

In FIG. 24, descriptions are given based on an example embodiment, in which the condenser 50 and the applicator 60 horizontally move and form the division line DL, but example embodiments are not limited thereto, and the chuck table, instead of the condenser 50 and the applicator 60 may move horizontally to form the division line DL.

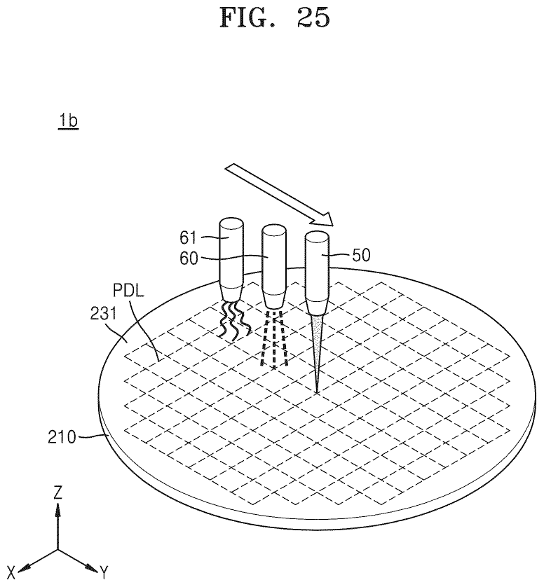

FIG. 25 is a schematic perspective view of a semiconductor processing apparatus 1b, according to an example embodiment.

Referring to FIG. 25, the semiconductor processing apparatus 1b may include the chuck table (40 in FIG. 9), the condenser 50, the applicator 60, and a curing device 61. The semiconductor processing apparatus 1b may include a device for forming the division line (DL in FIG. 2) on the laminate P220.

Hereinafter, duplicate descriptions of the semiconductor processing apparatus 1b in FIG. 25 and the semiconductor processing apparatus 1a in FIG. 24 are omitted, and only differences therebetween are described. In some example embodiments, the chuck table, the condenser 50, and the applicator 60 of the semiconductor processing apparatus 1b may be substantially the same as the chuck table, the condenser (50 in FIG. 24), and the applicator (60 in FIG. 24) described with reference to FIG. 24, respectively.

The curing device 61 may cure a coating solution. In some example embodiments, the curing device 61 may be configured to emit ultraviolet or infrared rays, and the coating solution may include a photo-curable material. In other words, the curing device 61 may be configured to photo-cure the coating liquid. In some example embodiments, the curing device 61 may be configured to emit ultraviolet or infrared rays, and the coating solution may include a thermosetting material. In other words, the curing device 61 may be configured to thermally cure the coating solution. In some example embodiments, the curing device 61 may be configured to emit hot air, and may thermally cure the coating solution.

The curing device 61, the applicator 60, and the condenser 50 may be arranged in a line. The curing device 61, the applicator 60, and the condenser 50 may move simultaneously in the same direction. In some example embodiments, the curing device 61, the applicator 60, and the condenser 50 may move in a line along the partition due line PDL. For example, the condenser 50, the applicator 60, and the curing device 61 may be sequentially arranged in the moving direction of the condenser 50. Accordingly, the condenser 50, the applicator, and the curing device 61 may pass the same point in sequence.

In FIG. 25, descriptions are given based on an example embodiment, in which the condenser 50, the applicator 60, and the curing device 61 horizontally move and form the division line DL, but example embodiments are not limited thereto, and the chuck table, instead of the condenser 50, the applicator 60, and the curing device 61, may move horizontally to form the division line DL.

While the inventive concepts has been particularly shown and described with reference to some example embodiments thereof, it will be understood that various changes in form and details may be made therein without departing from the spirit and scope of the following claims.

What is claimed is:

1. A semiconductor chip comprising:
a substrate;
an active layer on the substrate; and
a coated layer on side surfaces of the active layer and surrounding the side surfaces of the active layer,
wherein an average roughness of the side surfaces of the active layer is greater than an average roughness of an upper surface of the active layer, and
at least a portion of the substrate contacts the coated layer.

2. The semiconductor chip of claim 1, wherein the coated layer is a conformal layer on the side surfaces of the active layer.

3. The semiconductor chip of claim 1, wherein a horizontal width of the active layer decreases away from the substrate.

4. The semiconductor chip of claim 1, wherein the side surfaces of the active layer comprise at least one crack.

5. The semiconductor chip of claim 4, wherein the coated layer fills the crack of the active layer.

6. The semiconductor chip of claim 1, wherein
a first region of the upper surface of the substrate is in contact with the active layer,
a second region of the upper surface of the substrate is in contact with the coated layer, and
an average roughness of the first region of the upper surface of the substrate is less than an average roughness of the second region of the upper surface of the substrate.

7. The semiconductor chip of claim 6, wherein
the substrate comprises at least one crack in the upper surface thereof, and
the crack is in the second region of the upper surface of the substrate.

8. The semiconductor chip of claim 7, wherein the coated layer fills the crack of the substrate.

9. The semiconductor chip of claim 1, wherein an area of a lower surface of the active layer is less than an area of the upper surface of the substrate.

10. The semiconductor chip of claim 1, wherein
the side surfaces of the active layer covered by the coated layer, are not exposed to an outside, and
the upper surface of the active layer is exposed to an outside.

11. A semiconductor chip comprising:
a substrate;
a plurality of active layers on the substrate and apart from each other in a horizontal direction; and
a coated layer in contact with side surfaces of the plurality of active layers and an upper surface of the substrate,
wherein a horizontal width of each of the plurality of active layers decreases away from the substrate.

12. The semiconductor chip of claim 11, wherein
the plurality of active layers comprise a first active layer and a second active layer,
a first side surface of the first active layer and a second side surface of the second active layer face each other,
the first side surface and the second side surface comprise sidewalls of a division line,
a portion of the upper surface of the substrate comprises a bottom of the division line, and
the coated layer is a conformal layer on the sidewalls and the bottom of the division line.

13. The semiconductor chip of claim 12, wherein an average roughness of each of the sidewalls and the bottom of the division line is greater than an average roughness of the upper surface of the plurality of active layers.

14. The semiconductor chip of claim 12, further comprising:
a plurality of cracks in the sidewalls and the bottom of the division line,
wherein the coated layer fills the plurality of cracks on the sidewalls and the bottom of the division line.

15. The semiconductor chip of claim 12, wherein
a distance between the sidewalls comprising the division line decreases toward the substrate, and
the bottom of the division line has a rounded shape.

16. A manufacturing method of a semiconductor chip, the manufacturing method comprising:
forming a protection layer on an active layer of a substrate;
removing a portion of the protection layer and a portion of the active layer along a partition due line inside the active layer;
forming a coated layer in a space where the portion of the protection layer and the portion of the active layer are removed; and
removing the protection layer on the active layer.

17. The manufacturing method of claim 16, wherein the removing includes removing the portion of the protection layer and the portion of the active layer using a laser ablation process.

18. The manufacturing method of claim 16, wherein the forming the coated layer includes forming the coated layer by applying a coating solution into the space using a spray method.

19. The manufacturing method of claim 16, wherein the forming the coated layer includes forming the coated layer by applying a coating solution into the space using a brush method.

20. The manufacturing method of claim 16, further comprising:
after the forming of the coated layer, curing the coated layer by irradiating heat or light on the coated layer.
